(19) United States
(12) Patent Application Publication
(10) Pub. No.: US 2014/0354329 A1
(43) Pub. Date: Dec. 4, 2014

(54) ELECTRONIC DEVICE FOR FUNCTION RESETTING OF PINS AND METHOD THEREOF

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: YA-GUO WANG, Shenzhen (CN); CHUN-CHING CHEN, New Taipei (TW)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/251,317

(22) Filed: Apr. 11, 2014

(30) Foreign Application Priority Data
May 30, 2013 (CN) 2013102088084

(51) Int. Cl. H03K 19/0175

(52) U.S. Cl. CPC H03K 19/017581
USPC 326/38

(57) ABSTRACT

An electronic device includes a chip and a pin configuration apparatus. The chip includes a plurality of pins with different functions. The pin configuration apparatus is used for resetting the pins from being configured to execute a first function to being configured to execute a second function.

### FIELD

The present disclosure relates to electronic devices, particularly to an electronic device for resetting pin function.

### BACKGROUND

System programs of electronic devices with a central processing unit (CPU), such as computers and mobile phones, are burned in a flash storage of the device. The CPU often includes two pins with a Universal Asynchronous Receiver/Transmitter (UART) function for loading the system programs. However, after the system programs are burned in the flash storage through the CPU, the pins with UART function of the CPU are idle.

### BRIEF DESCRIPTION OF THE FIGURE

Many aspects of the embodiments can be better understood with reference to the following drawings. The components in the drawings are not necessarily drawn to scale, the emphasis instead being placed upon clearly illustrating the principles of the electronic device and function resetting method thereof. Like reference numerals designate corresponding parts throughout the several views of the drawings.

FIG. 1 is a block diagram of an electronic device in accordance with an embodiment.

FIG. 2 is a block diagram of the electronic device of FIG. 1 according to a first exemplary embodiment.

FIG. 3 is a block diagram of the electronic device of FIG. 2 after resetting function of pins.

FIG. 4 is a flowchart of a function resetting method in accordance with the embodiment.

### DETAILED DESCRIPTION

In general, the word “module,” as used herein, refers to logic embodied in hardware or firmware, or to a collection of software instructions, written in a programming language, for example, Java, C, or assembly. One or more software instructions in the modules may be embedded in firmware, such as in an EPROM. Modules may comprise connected logic units, such as gates and flip-flops, and may comprise programmable units, such as programmable gate arrays or processors. The modules described herein may be implemented as either software and/or hardware modules and may be stored in any type of computer-readable medium or other computer storage system. Embodiments of the present disclosure will be described with reference to the drawings.

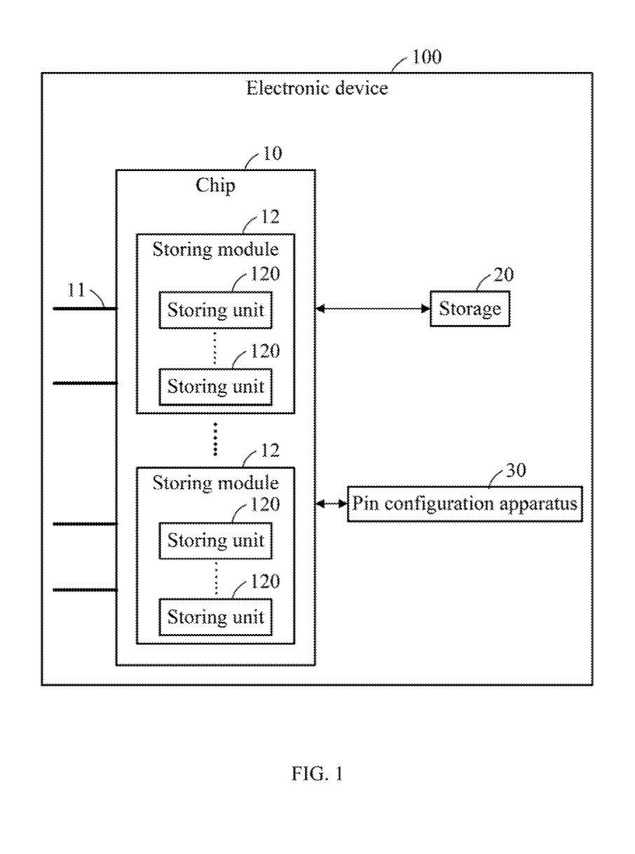

FIG. 1 shows an electronic device 100 in accordance with an embodiment of the disclosure. The electronic device 100 includes a plurality of pins 11 and is capable of resetting the pins 11 to designate to execute different functions. In the embodiment, the electronic device 100 is a DVD player or a mobile phone.

The electronic device 100 can include a chip 10, storage 20, and a pin configuration apparatus 30.

The chip 10 includes a plurality of pins 11 with different functions and a plurality of storing modules 12 corresponding to the pins 11 in a one-to-one relationship. The storing modules 12 store parameters for initializing different functions which are different from each other. Each of the storing modules 12 stores parameters related to a same function and includes a plurality of storing unit 120 for storing the corresponding parameters. Each of the pins 11 matches parameters stored in one of the storing units 120 of the corresponding storing module 12, thus the pin 11 is designated to execute a corresponding function based on the parameters of the matched storing module 12. For example, the storing module 12 includes two storing units 120. One of the storing modules 12 stores first parameters related to UART function, and the other storing module 12 stores second parameters related to General Purpose Input/Output (GPIO) function. The pin 11 matches one of the storing units 120 of the storing module 12 with the first parameters for designating the UART function. The pin 11 matches one of the storing units 120 of the storing module 12 with the second parameters for designating the GPIO function. In one embodiment, the chip 10 is a CPU.

The storage 20 is used for storing programs. In one embodiment, the storage 20 is a flash storage.

The pin configuration apparatus 30 is used for resetting pin functions. The pin configuration apparatus 30 includes a searching unit 31, a resetting unit 32, and an initialization unit 34. The searching unit 31, the resetting unit 32, and the initialization unit 34 are executed based on the program stored in the storage 20.

The searching unit 31 is used for searching the pins designated to execute the first function. In one embodiment, the searching unit 31 searches the pins based on the matched first parameters.

The resetting unit 32 can be used for resetting the searched pins. In at least one embodiment, the resetting unit 32 resets the searched pins to match the second parameters. In at least one embodiment, the resetting unit 32 can change the first parameters of the storing unit 120 into the second parameters.

The initialization unit 34 can be used for initializing the reset pins to be enabled for executing the second function based on the matched second parameters.

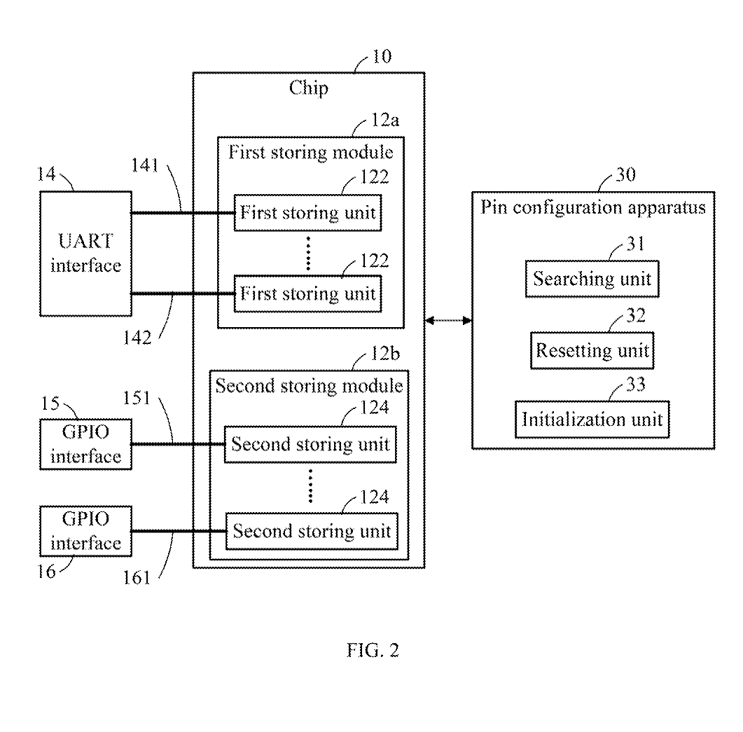

FIG. 2 shows a first exemplary embodiment of the electronic device 100. The chip 10 includes a first pins 141, a second pin 142, a third pin 151, and a fourth pin 161. The first pin 141 and the second pin 142 are connected to a UART interface 14 simultaneously, and the third pin 151 and the fourth pin 152 are connected to two GPIO interfaces 15, 16 respectively. The chip 10 further includes a first storing module 12a and a second storing module 12b. The first storing module 12a includes a plurality of first storing units 122 for storing first parameters related to the UART function. The second storing module 12b includes a plurality of second storing units 124 for storing second parameters related to the GPIO function. The first pin 141 and the second pin 142 are respectively matched with one of the first storing units 122, the third pin 151 and the fourth pin 161 are respectively matched with one of the second storing units 124. In others embodiments, the chip 10 further includes a third storing module 12c for storing parameters related to Sony/Philips Digital Interface (SPDI) type pin, and a fourth storing module 12d for storing parameters related to serial peripheral interface (SPI) type pin.

The searching unit 31 searches the first pin 141 and the second pin 142 with UART function which are connected to the UART interface 14.

The resetting unit 32 respectively resets the first pin 141 and the second pin 142 to be matched with one of the second storing units 124 of the second storing module 12b.

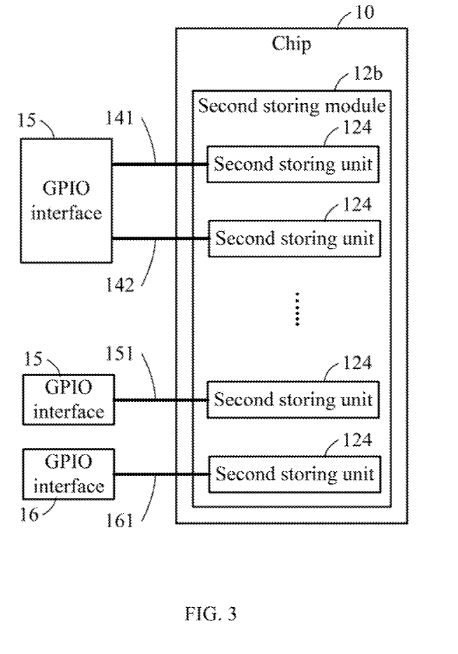

FIG. 3 shows an embodiment of the electronic device 100 with the first pin 141 and the second pin 142 reset for executing the GPIO function. The initialization unit 34 is used for initializing first pin 141 and the second pin 142 to be enabled for executing GPIO function based on the second parameters of the second storing units 124 (as shown in FIG. 3).

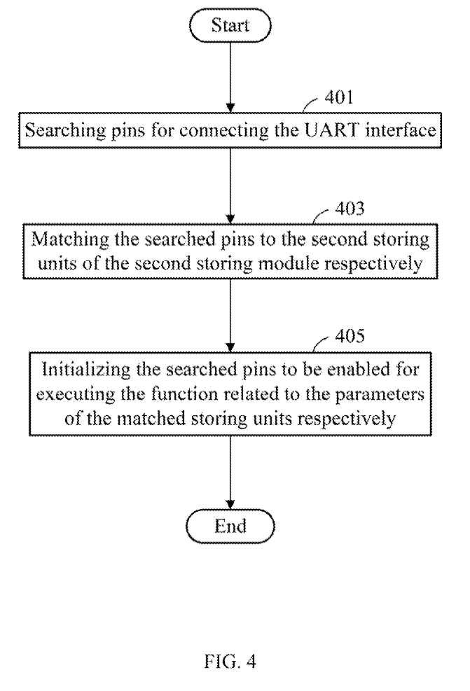

FIG. 4 shows a function resetting method applied to an electronic device 100. The electronic device 100 includes a chip 10 and a pin configuration apparatus 30. The chip 10 comprises a plurality of pins 11 and a first storing module 12a, and a second storing module 12b. The first storing module 12a stores first parameters related to the UART function. The second storing module 12b stores second parameters related to the GPIO function. The pin configuration apparatus 30 for resetting functions of pins includes a searching unit 31, a resetting unit 32, and an initialization unit 34. The function resetting method includes the following steps.

In 401, the searching unit searches the pins designated to execute a first function. In one embodiment, the searching unit searches the pins matching first parameters.

In 403, the resetting unit resets the searched pins. In one embodiment, the resetting unit resets the searched pins to match the second parameters. In other embodiments, the resetting unit can change the first parameters of the storing unit into the second parameters.

In 405, the initialization unit initializes the reset pins to be enabled for executing the second function based on the second parameters.

In use, the idle pins of the chip can be reset for enabling execution of other functions, thus the utilization of the pins of the chip is improved.

While various embodiments have been described, the disclosure is not to be limited thereto. Various modifications and similar arrangements (as would be apparent to those skilled in the art) are also intended to be covered. The embodiments discussed are illustrative only, and are not intended to limit the scope of the following claims.

What is claimed is:

1. An electronic device, comprising:
a chip with a plurality of pins; and
a pin configuration apparatus connected to the chip;
wherein the pins are designated to execute a first function, the pin configuration apparatus resets the pins, enabling the pins to execute a second function.

2. The electronic device of claim 1, wherein the pin configuration apparatus comprises a searching unit, a resetting unit, and an initialization unit; the searching unit searches the pins designated for executing the first function, the resetting unit resets the searched pin, the initialization unit initializes the reset pin to be enabled for executing a second function based on the second parameters.

3. The electronic device of claim 2, wherein the chip includes a first storing module and a second storing module; the first storing module stores first parameters related to the first function; the second storing module stores second parameters related to the second function; the pins related to the first function match the first parameters of the first storing module; the searching unit is configured to search the pins matching the first parameters; and the resetting unit is configured to reset the searched pin to match second parameters.

4. The electronic device of claim 3, wherein the first parameters are used for initializing Universal Asynchronous Receiver/Transmitter function.

5. The electronic device of claim 3, wherein the second parameters are used for initializing General Purpose Input/Output function.

6. A pin configuration apparatus connect to a chip with a, the chip comprising a plurality of pins being designed to execute different functions and a plurality of storing modules which corresponding to the pins in a one-to-one relationship; the storing module for storing parameters for initializing different functions; the pin configuration apparatus comprising:
a searching unit;
a resetting unit; and
an initialization unit;
wherein the searching unit searches the pins designated to execute a first function, the resetting unit resets the searched pin, the initialization unit initializes the reset pin to be enabling the reset pin execute a second function.

7. The pin configuration apparatus of claim 6, wherein the chip includes a first storing module and a second storing module; the first storing module stores first parameters related to the first function; the second storing module stores second parameters related to the second function; the pins related to the first function match the first parameters of the first storing module; the searching unit searches the pins matched the first parameters; the resetting unit resets the searched pin to match second parameters.

8. The pin configuration apparatus of claim 7, wherein the first parameters are used for initializing Universal Asynchronous Receiver/Transmitter function.

9. The pin configuration apparatus of claim 7, wherein the second parameters are used for initializing General Purpose Input/Output function.

10. A function resetting method applied to an electronic device; the electronic device comprising a chip with a plurality of pins and a plurality of storing modules corresponding to the pins in a one-to-one relationship; the function resetting method comprising:
searching pins designated to execute a first function;
resetting the searched pins; and
initializing the reset pin to be enabled to execute a second function.

11. The function resetting method of claim 10, wherein the chip includes a first storing module and a second storing module; the first storing module stores first parameters related to the first function; the second storing module stores second parameters related to the second function; the pins designated to the first function match the first parameters of the first storing module; the step of resetting the searched pin comprising:
resetting the searched pins to match second parameters.

12. The function resetting method of claim 11, wherein the first parameters are used for initializing Universal Asynchronous Receiver/Transmitter function.

13. The function resetting method of claim 11, wherein the second parameters are used for initializing General Purpose Input/Output function.
